(19) United States
(12) Patent Application Publication
(10) Pub. No.: US 2008/0113505 A1
(43) Pub. Date: May 15, 2008

(54) METHOD OF FORMING A THROUGH-SUBSTRATE VIA

(76) Inventors: Terry G. Sparks, Austin, TX (US); Syed M. Alam, Austin, TX (US); Ritwik Chatterjee, Austin, TX (US); Shahid Rauf, Pleasanton, CA (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/558,988

(22) Filed: Nov. 13, 2006

(51) Int. Cl. H01L 21/768

(52) U.S. Cl. 438/637; 438/667; 438/687; 257/E21.577; 257/E21.586

(57) ABSTRACT

A method for achieving a through-substrate via through a substrate having active circuitry on a first major surface begins by forming a hole into the substrate through the first major surface. The hole is lined with a conductive layer. A dielectric layer is deposited over the conductive layer. This deposition is performed in a manner that causes the dielectric layer to be substantially conformal. Conductive material is formed over first dielectric layer. A second major surface of the substrate is etched to expose the conductive material.

### FIELD OF THE INVENTION

This invention relates generally to semiconductor devices, and more specifically, to semiconductor devices having through-substrate vias.

### BACKGROUND

Stacking of semiconductor devices into a single package is desirable to decrease the amount of space or area needed for the semiconductor device. This decrease in space allows for products, such as cell phones, to be smaller. When two semiconductor devices are stacked together, the devices can be arranged so that the top of each of the devices are sandwiched together between each semiconductor device's substrate. However, when more than two semiconductor devices are stacked together additional interconnects within the semiconductor devices are needed. Prior art approaches have formed copper vias surrounded by thin dielectric layers. The thin dielectric layers of different interconnects are separated by a silicon substrate that at the frequencies of interest (100-300 MHz) acts like a conductor and decreases electrical performance. In addition, noise and interference exists in the silicon substrate that also decreases electrical performance. Therefore, a need exists for interconnects that have a minimum negative effect on electrical performance.

### BRIEF DESCRIPTION OF THE DRAWINGS

The invention is illustrated by way of example and is not limited by the accompanying figures, in which like references indicate similar elements.

FIG. 1 illustrates a cross-section of a portion of a semiconductor device including a semiconductor substrate, active circuitry, and a first dielectric layer in accordance with an embodiment of the invention;

FIG. 2 illustrates the portion of the semiconductor device of FIG. 1 after forming a trench (hole, via, or opening) within the semiconductor substrate and removing a portion of the first dielectric layer in accordance with an embodiment of the invention;

FIG. 3 illustrates the portion of the semiconductor substrate of FIG. 2 after forming a second dielectric layer in the trench in accordance with an embodiment of the invention;

FIG. 4 illustrates the portion of the semiconductor substrate of FIG. 3 after forming a first barrier layer and a first metal layer in accordance with an embodiment of the invention;

FIG. 5 illustrates the portion of the semiconductor substrate of FIG. 4 after forming the third dielectric layer in accordance with an embodiment of the invention;

FIG. 6 illustrates the portion of the semiconductor substrate of FIG. 5 after forming a second barrier layer and a deposited metal layer in accordance with an embodiment of the invention;

FIG. 7 illustrates the portion of the semiconductor device of FIG. 6 after forming a signal line in accordance with an embodiment of the invention;

FIG. 8 illustrates the portion of the semiconductor device of FIG. 7 after removing portions of the layers that overly the first dielectric layer and extend outside the trench in accordance with an embodiment of the invention;

FIG. 9 illustrates a top view of the portion of the semiconductor device of FIG. 8 showing a through-substrate via in accordance with an embodiment of the invention;

FIG. 10 illustrates the portion of the semiconductor device of FIG. 8 after forming an interconnect in accordance with an embodiment of the invention;

FIG. 11 illustrates an enlarged portion of the semiconductor device illustrated FIG. 10 in accordance with an embodiment of the invention;

FIG. 12 illustrates a portion of the semiconductor device with the through-substrate via in accordance with an embodiment of the invention;

FIG. 13 illustrates the portion of the semiconductor device of FIG. 12 after removing portions of the semiconductor substrate in accordance with an embodiment of the invention; and

FIG. 14 illustrates the portion of the semiconductor device of FIG. 10 after removing a portion of the semiconductor substrate to expose the signal line in accordance with an embodiment of the invention

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the invention.

### DETAILED DESCRIPTION OF THE DRAWINGS

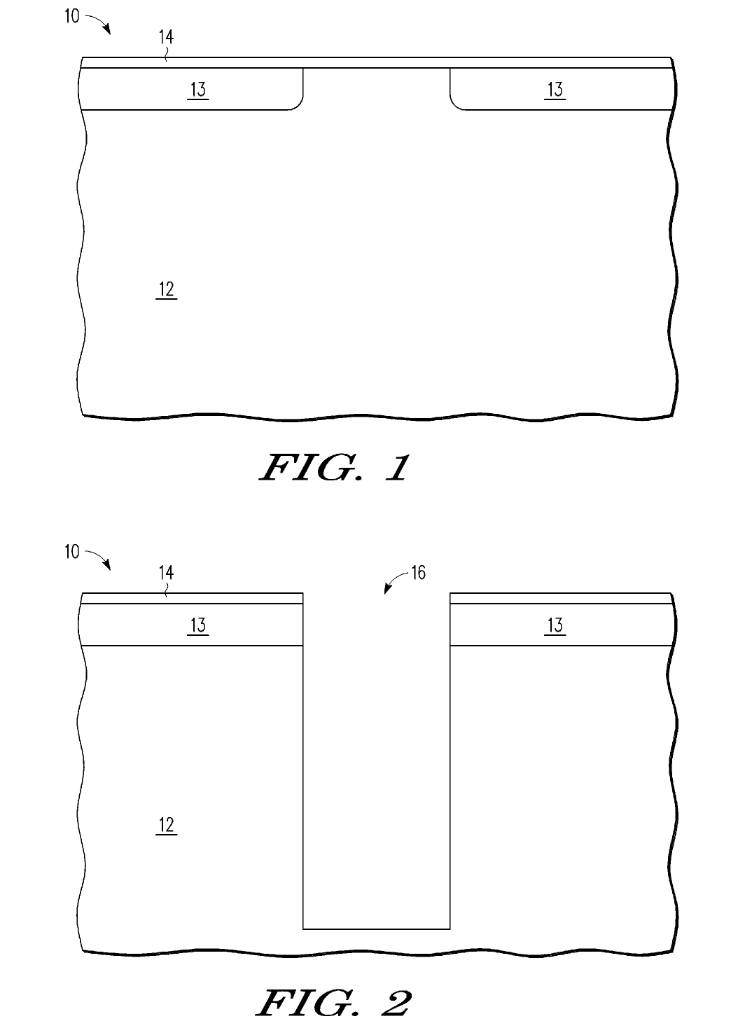

FIG. 1 illustrates a cross-section of a portion of a semiconductor device 10 including a semiconductor substrate 12, active circuitry 13, and a first dielectric layer 14 in accordance with an embodiment of the invention. The semiconductor substrate 12 can be any semiconductor material or combinations of materials, such as gallium arsenide, silicon germanium, silicon-on-insulator (SOI) (e.g., fully depleted SOI (FDSOI)), silicon, monocrystalline silicon, the like, and combinations of the above. The semiconductor substrate has a first major surface (e.g., the top surface), which is illustrated in FIG. 1, and a second major surface (e.g., the bottom surface), which will be illustrated in another figure. The semiconductor substrate 12 as shown in FIG. 1 has undergone processing to form active circuitry 13, as known to a skilled artisan. The active circuitry 13 may include any active circuits, such as N-MOS and P-MOS transistors, at least one layer of metal for coupling the N-MOS and P-MOS transistors, and dielectric layers (e.g., interlevel dielectric layers). Although active circuitry 13 is not shown in a region of the semiconductor substrate 12, this region is not protected during prior processing and thus may include dielectric layers, etc., but this region does not include any circuitry that is to be present in the final structure and hence, is not active circuitry 13. The first dielectric layer 14 formed over the semiconductor substrate 12, in one embodiment, is formed over the active circuitry 13. The first dielectric layer 14 can be any suitable dielectric, such as silicon dioxide. The first dielectric layer 14 may be formed by any suitable process, such as chemical vapor deposition (CVD), physical vapor deposition (PVD), the like, and combinations of the above.

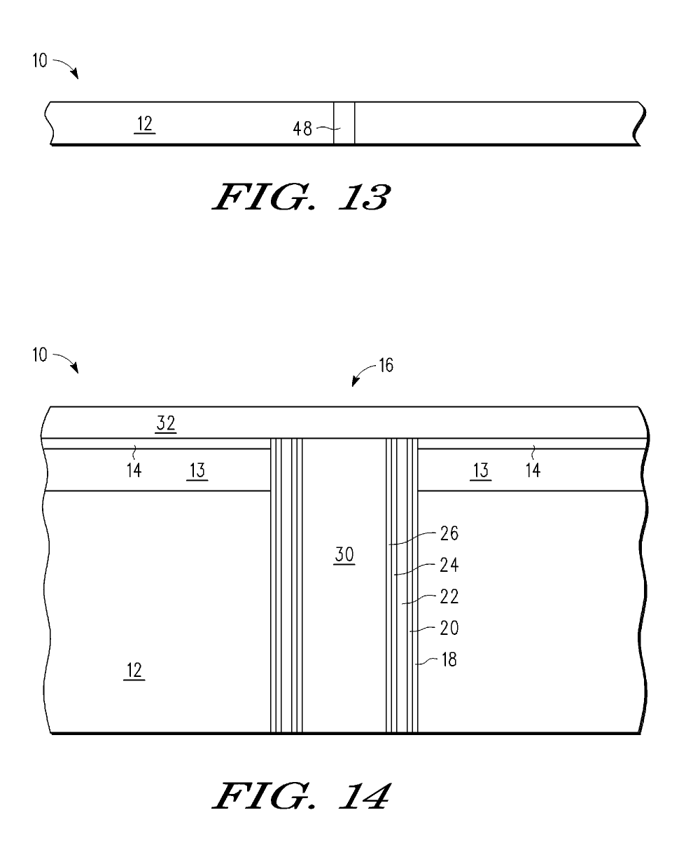

FIG. 2 illustrates the portion of the semiconductor device 10 of FIG. 1 after forming a trench (hole, via, or opening) 16 within the semiconductor substrate 12 and removing a portion of the first dielectric layer 14. As previously discussed, the portion of the semiconductor device 10 where the trench 16 is formed did not include active circuitry 13. As will become apparent when discussing FIGS. 12 and 13, the semiconductor substrate 12 may be approximately 14 times thicker than the depth of the trench 16 and the width of the trench 16 may be approximately 1/20 to approximately ½ the depth of the trench. In one embodiment, the width of the trench 16 is approximately 5 to approximately 25 microns. In one embodiment, the thickness of the semiconductor substrate 12 is approximately 700 microns thick. To remove a portion of the first dielectric layer 14 and form the trench 16 an etch may be performed. The portion of the first dielectric layer 14 that overlies the subsequently formed trench 16 is removed. This portion may be removed during the etch, for example. In one embodiment, a plasma etch using a fluorocarbon chemistry such as CF₄ or SF₆ may be used to form the trench 16. Other processes, such as an etch-deposition-etch sequence process, may be used.

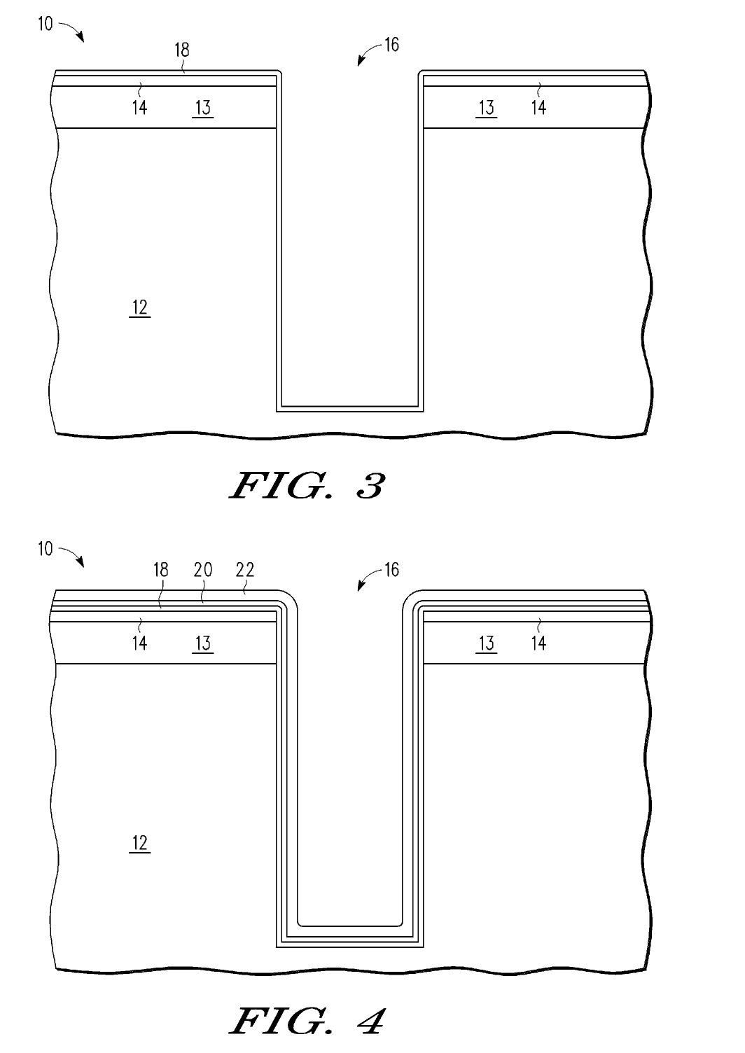

FIG. 3 illustrates the portion of the semiconductor device 10 of FIG. 2 after forming a second dielectric layer 18 in the trench 16. The second dielectric layer 18 may be formed by any suitable process such as CVD, PVD, the like, or combinations of the above. In one embodiment, the second dielectric layer 18 is a nitride, such as silicon nitride. The second dielectric layer 18, in one embodiment, is approximately 0.5 microns thick.

FIG. 4 illustrates the portion of the semiconductor device 10 of FIG. 3 after forming a first barrier layer 20 and a first metal layer 22. The first barrier layer 20 may be formed by any suitable process, such as CVD, PVD, the like, or combinations of the above. In one embodiment, the first barrier layer 20 is approximately 0.5 microns thick. The material chosen for the first barrier layer 20 depends on the material chosen for the subsequently formed second metal layer. The material for the first barrier layer 20 should be chosen is to i) decrease diffusion of the metal from the subsequently formed second metal layer into the second dielectric layer 18, ii) promote adhesion of the subsequently formed second metal layer to the second dielectric layer 18, or iii) both. Hence, the first barrier layer 20 may be a barrier layer for metal diffusion, an adhesion layer, or both. For example, if the subsequently formed third metal layer includes copper, the first barrier layer 20 may be Ta, TiN, the like, or combinations of the above. Hence, the first barrier layer 20 may be a metal or metal alloy. The first metal layer 22 may be any suitable metal, such as copper or a conductive material that includes copper. The first metal layer 22, in one embodiment, may be approximately 0.5 microns to approximately 5 microns thick, such as approximately 1 micron thick. The thickness of the first metal layer 22 should be chosen so that it is thick enough to carry current (e.g., ground current), but not too thick that is takes away too much space from the subsequently formed signal line or has a profile that is too difficult to control during processing. As will be better understood after further processing, the first metal layer 22 may be a ground line. The first metal layer 22 may be formed by depositing (e.g., by CVD, PVD, the like, or combinations of the above) the first metal layer 22 or depositing (e.g., by CVD, PVD, the like, or combinations of the above) a portion of the first metal layer 22 and then plating the rest of the first metal layer 22 to achieve the desired thickness. In other words, the first metal layer 22 may be formed by one process, such as PVD, or by multiple processes, such as a PVD followed by plating. In one embodiment, the plating can be electroplated or electrolessly plated. Thus, in one embodiment, the barrier layer is formed by depositing PVD copper and in another embodiment by depositing using PVD copper and then plating copper over the PVD copper layer. Thus, in one embodiment, the first metal layer 22 is a seed layer, such as a plating seed layer.

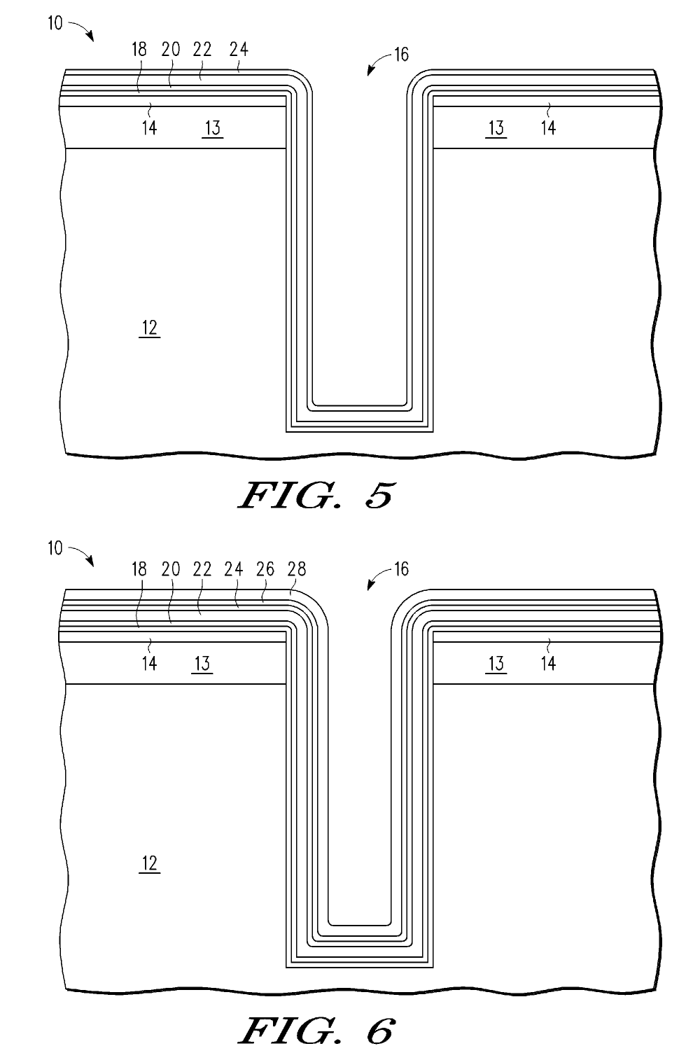

FIG. 5 illustrates the portion of the semiconductor device 10 of FIG. 4 after forming the third dielectric layer 24. The third dielectric layer 24 may be formed by any suitable process such as CVD, PVD, the like, or combinations of the above. In one embodiment, the third dielectric layer 24 is a nitride, such as silicon nitride. The third dielectric layer 24, in one embodiment, is approximately 0.5 microns thick.

FIG. 6 illustrates the portion of the semiconductor device 10 of FIG. 5 after forming a second barrier layer 26 and a deposited metal layer 28. The second barrier layer 26 may be formed by any suitable process, such as CVD, PVD, the like, or combinations of the above. In one embodiment, the second barrier layer 26 is approximately 0.5 microns thick. The material chosen for the second barrier layer 26 depends on the material used for the subsequently formed deposited metal layer 28. The material used for the second barrier layer 26 should be chosen as to i) decrease diffusion of the metal from the deposited metal layer 28 into the third dielectric layer 24, ii) promote adhesion of the deposited metal layer 28 to the third dielectric layer 24, or iii) both. Hence, the second barrier layer 26 may be a barrier layer for metal diffusion, an adhesion layer, or both. For example, if the deposited metal layer 28 includes copper, the second barrier layer 26 may be Ta, TiN, the like, or combinations of the above. Hence, the second barrier layer 26 may be a metal or metal alloy. The deposited metal layer 28 may be any suitable metal, such as copper or a conductive material that includes copper. In one embodiment, the deposited metal layer 28 is approximately 0.5 to approximately 5 microns thick. The deposited metal layer 28 can be formed by any suitable deposition process, such as CVD, PVD, the like, or combinations of the above. In one embodiment, the deposited metal layer 28 is a seed layer, such as a plating seed layer.

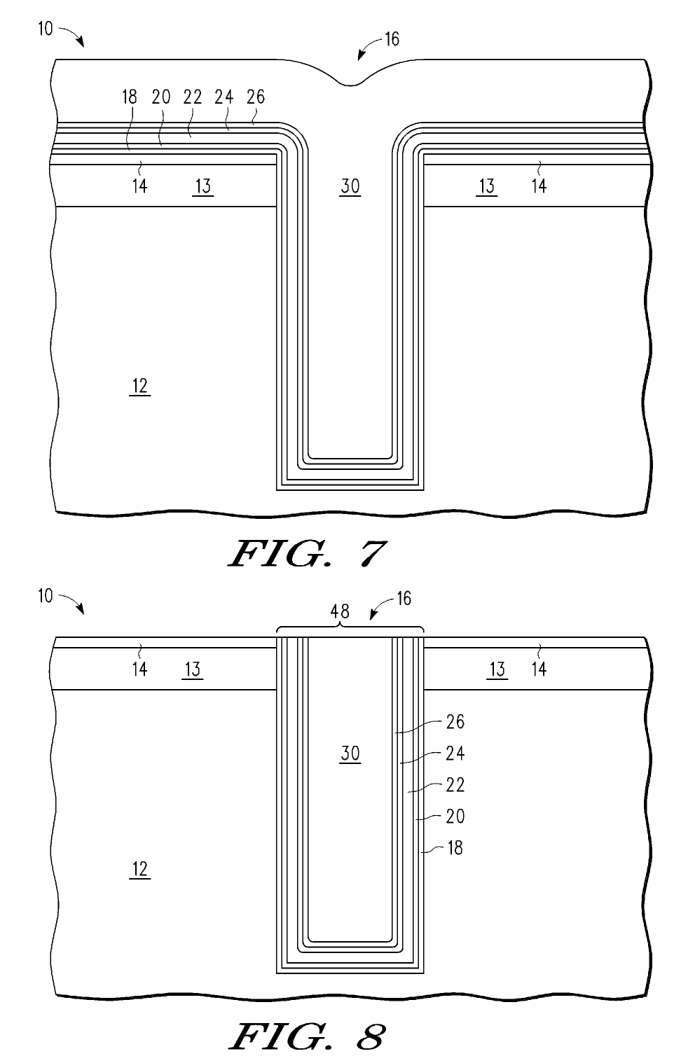

FIG. 7 illustrates the portion of the semiconductor device 10 of FIG. 6 after forming a signal line 30. In one embodiment, the signal line 30 is a combination of a plated metal layer formed over the deposited metal layer 28 of FIG. 6 and the deposited metal layer 28. To form the signal line 30, in one embodiment, a metal layer including copper, such as copper, is plated over a deposited metal layer including copper, such as copper. The plated metal may be plated by electroplating, for example, and the deposited metal layer can be formed by PVD, for example. The plated metal layer has a thickness that fills the remainder of the trench 16 that is empty prior to the plating process. The signal line 30 in one embodiment is approximately 3 to approximately 23 microns thick, such as approximately 22 microns thick. A skilled artisan recognizes that these thicknesses (and all others discussed herein) depend on the size of the trench 16. A skilled artisan should also recognize that the layers 18, 20, 22, 24, 26, and 28 as described above, are conformal layers meaning that they are substantially conformal layers, because the layers 18, 20, 22, 24, 26, and 28 may not be perfectly conformal. For example, polysilicon is one of the most conformal materials used in semiconductor processing, whereas photoresist is one of the least conformal layers used in semiconductor processing. In addition, the layers 18, 20, 22, 24, 26, 28 are each formed to line the trench 16.

FIG. 8 illustrates the portion of the semiconductor device 10 of FIG. 7 after removing portions of the layers 18, 20, 22, 24, 26, and 30 that overlie the first dielectric layer 14 and extend outside the trench 16. In one embodiment, portions of the layers 18, 20, 22, 24, 26, and 30 that overlie the first dielectric layer 14 and extend outside the trench 16 are removed using a CMP process. In one embodiment, the CMP process can endpoint on the first dielectric layer 14. In one embodiment, the CMP process is used to form a substantially planar surface above the trench 16 that is substantially coplanar with a top surface of the first dielectric layer 14. In other embodiments, an etch back process could be used to remove the portions of the layers 18, 20, 22, 24, 26, and 30 that overlie the first dielectric layer 14 and extend outside the trench 16. After removing the portions of the layers 18, 20, 22, 24, 26, and 30 that overlie the first dielectric layer 14 and extend outside the trench 16, a through-substrate via 48 is formed within the trench 16. As will be better understood after further discussion, the portions of the bottom of the through-substrate via 48 will be exposed so that the through-substrate via 48 is capable of conducting signals from the top of the semiconductor device 10 to the bottom of the semiconductor device 10.

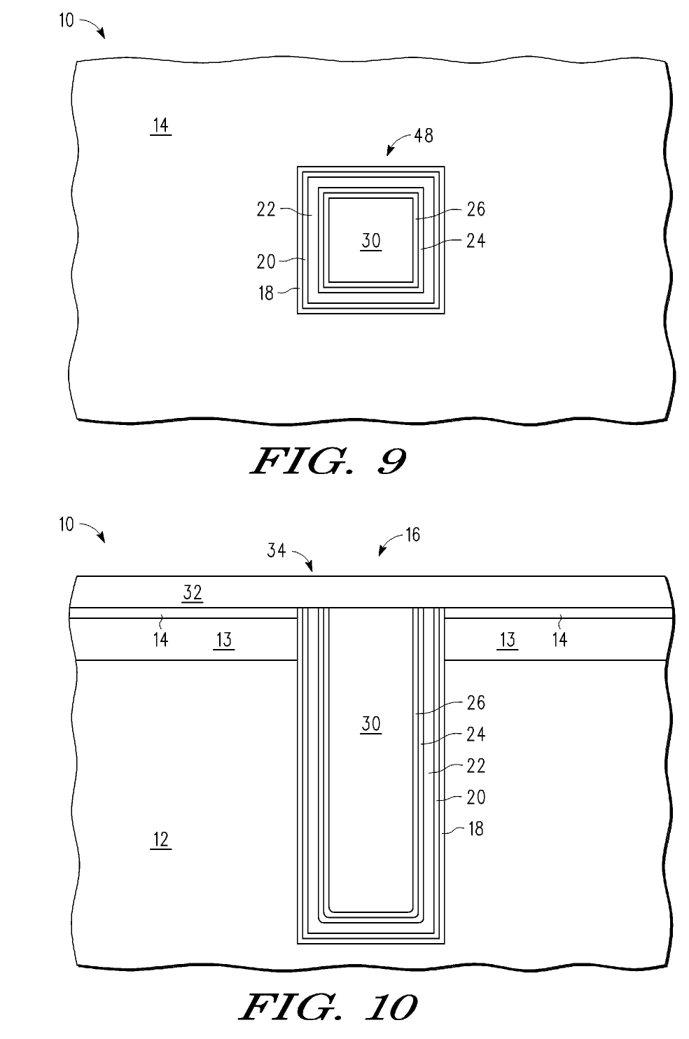

FIG. 9 illustrates a top view of the portion of the semiconductor device 10 of FIG. 8 showing the through-substrate via 48. In the portion illustrated, the first dielectric layer 14 surrounds the through-substrate via 48. The through-substrate via 48 has a conductive region (the signal line 30) in the center. Surrounding the signal line 30 is the second barrier layer 26, which is surrounded by the third dielectric layer 24. The third dielectric layer 24 is surrounded by the first metal layer 22, which is surrounded by the first barrier layer 20 and the second dielectric layer 18.

FIG. 10 illustrates the portion of the semiconductor device 10 of FIG. 8 after forming an interconnect 32. The interconnect 32 may include various metal and dielectric layers (i.e., various interconnect layers.) Region 34 of the through-substrate via 48 will be enlarged in the next figure to illustrate how at least a portion of the interconnect 32 may be coupled to the through-substrate via 48.

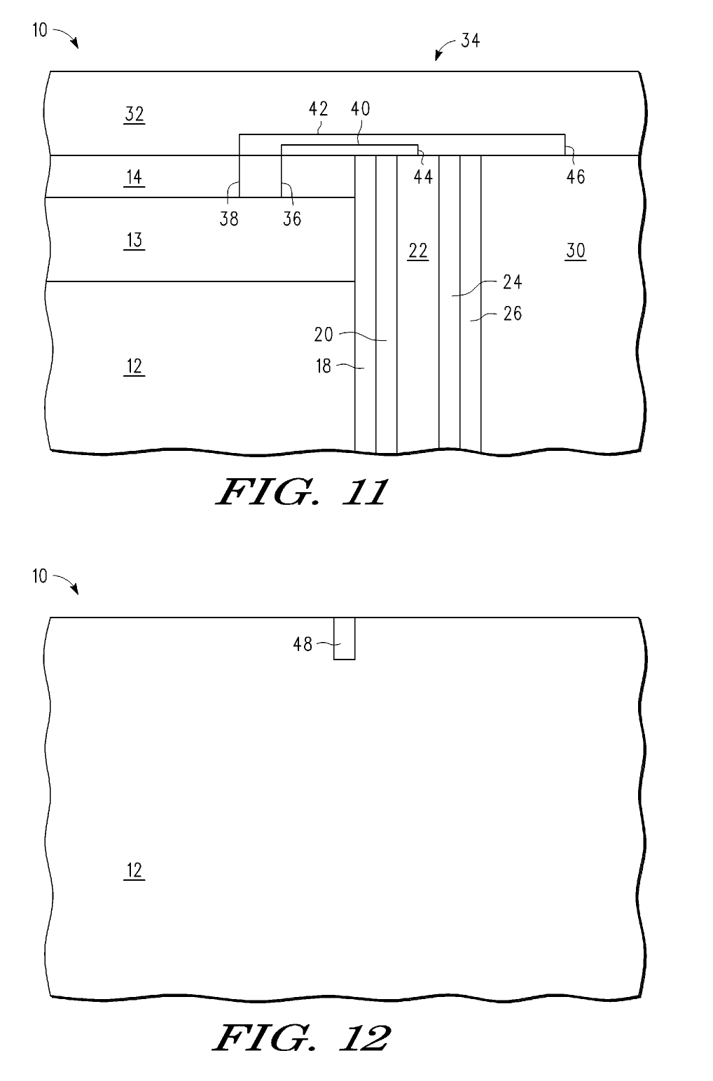

FIG. 11 illustrates an enlarged portion of the semiconductor device 10 illustrated in FIG. 10. More specifically, FIG. 11 illustrates how portions of the interconnect 32 in region 34 are coupled to portions of the interconnect 32. First via 36, first conductive line 40 and second via 44 couple a portion of the active circuitry 13 to the second metal layer 22. Thus, the first via 36 is between the first conductive line 40 and the active circuitry 13 and the second via 44 is between the first conductive line 40 and the second metal layer 22. Third via 38, second conductive line 42, and fourth via 46 couple a portion of the signal line 30 to the active circuitry 13. Thus, the third via 38 is between the second conductive line 42 and the active circuitry 13, and the fourth via 46 is between the second conductive line 40 and the signal line 30. In one embodiment, the first conductive line 40 is a ground line and the second conductive line 42 is a signal line. In one embodiment, the first conductive line 40 is a power supply line and the second conductive line 42 is a power supply line. In one embodiment, the first conductive line 40 is a positive power supply line and the second conductive line 42 is a ground line.

FIG. 12 illustrates a portion of the semiconductor device 10 with the through-substrate via 48 in accordance with an embodiment of the invention. (Although active circuitry 13, the first dielectric layer 14, and the interconnect 32 are still present, they are not illustrated in FIGS. 12 and 13 as they are so thin compared to the through-substrate via 48 and the semiconductor substrate 12 that they cannot be seen.) The semiconductor device 10 of FIG. 12 illustrates how shallow the through-substrate via 48 is relative to the entire semiconductor substrate 12. As previously discussed, the semiconductor substrate 12 may be approximately 14 times thicker than the depth of the trench 16 and the width of the trench 16 may be approximately ⅕ to approximately ½ the depth of the trench. The semiconductor substrate 12 also includes a second major surface (e.g., the bottom surface) as illustrated in FIG. 12.

FIG. 13 illustrates the portion of the semiconductor device 10 of FIG. 12 after removing portions of the semiconductor substrate, which in the embodiment illustrated is a majority (greater than 50%) of the semiconductor substrate. In one embodiment, approximately 650 microns of the semiconductor substrate 12 is removed. The portion of the semiconductor substrate 12 is removed as to expose the through-substrate via 48, or more specifically, the signal line 30 of the through-substrate via 48. The semiconductor substrate 12 can be thinned to expose the signal line 30 by using a grinding process. In one embodiment, a CMP process, an etch, or both may be performed. The etch can be a dry or wet etch. A dry etch may be used to decrease damage to the wafer during the grinding process. In one embodiment, the second major surface of the semiconductor substrate 12 is etched through a grinding process.

FIG. 14 illustrates the portion of the semiconductor device 10 of FIG. 10 after removing a portion of the semiconductor substrate 12 to expose the signal line 30. In addition, the layers 18, 20, 22, 24, and 26 are exposed after removing a portion of the semiconductor substrate 12. The result of the processing discussed is a through-substrate via that can couple different chips or circuits in stacked die or circuits.

By now it should be appreciated that there has been provided a method for forming a semiconductor device have interconnects, such as through-substrate vias that minimize the negative effect on electrical performance of the device. The through-substrate via 48 is a coaxial conductive structure as it includes two conductive regions that are insulated from each other. Having the second metal layer 22 surrounding and isolated from the signal line 30 decreases the capacitance between the signal line 30 and any adjacent signal lines (not illustrated) that may be present on the semiconductor device 10. This decrease in capacitance improves electrical performance and can extend the frequency range of operation for the semiconductor device 10. As discussed above, an additional dielectric layer and an additional metal layer than the interconnect in the prior art is formed in the through-substrate via. The additional metal layer can be coupled to ground via the interconnect 32 (at the top of the semiconductor device 10) or at the bottom of the semiconductor device 10 (not shown). Thus, the metal layer (and the signal line) should be thick enough so that electrical contact can be made to these layers either from the top or bottom of the semiconductor device 10.

Because the apparatus implementing the invention is, for the most part, composed of electronic components and circuits known to those skilled in the art, circuit details will not be explained in any greater extent than that considered necessary as illustrated above, for the understanding and appreciation of the underlying concepts of the invention and in order not to obfuscate or distract from the teachings of the invention.

In the foregoing specification, the invention has been described with reference to specific embodiments. However, one of ordinary skill in the art appreciates that various modifications and changes can be made without departing from the scope of the invention as set forth in the claims below. For example, although the top view of the through-substrate via in FIG. 9 is illustrated as a rectangle or square shape, other shapes such as a circle (with concentric layers) may be formed. In addition, a skilled artisan should recognize that layers, such as layer 14, may be unintentionally decreased in thickness during subsequent processing (e.g., during polishing) after the forming the layers. In addition, additional dielectric layers or other layers may be added to the through-substrate via, if desired. Accordingly, the specification and figures are to be regarded in an illustrative rather than a restrictive sense, and all such modifications are intended to be included within the scope of the invention. Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one. The term “plurality”, as used herein, is defined as two or more than two. The term another, as used herein, is defined as at least a second or more. The term “coupled”, as used herein, is defined as connected, although not necessarily directly, and not necessarily mechanically. Moreover, the terms “front”, “back”, “top”, “bottom”, “over”, “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

What is claimed is:

1. A method, comprising:
providing a substrate having active circuitry on a first major surface;
forming a hole in the substrate through the first major surface;
lining the hole with a conductive layer;
depositing a first dielectric layer over the conductive layer in a manner that is substantially conformal;
forming a conductive material over the first dielectric layer; and
etching a second major surface of the substrate to expose the conductive material.

2. The method of claim 1, further comprising depositing a second dielectric layer in the hole in a manner that is substantially conformal prior to the step of lining the hole with the conductive layer.

3. The method of claim 2, further comprising forming a first barrier layer over the first dielectric layer prior to the step of forming the first conductive layer.

4. The method of claim 3, further comprising forming a second barrier layer over the second dielectric layer in a manner that is substantially conformal prior to the step of lining the hole with the conductive layer.

5. The method of claim 3, wherein the steps of forming the first and second barrier layers are further characterized by the first and second barrier layers comprising a metal.

6. The method of claim 1, further comprising forming a seed layer over the first dielectric layer prior to the step of forming the conductive layer, wherein the step of forming the conductive material comprises plating.

7. The method of claim 6, wherein the step of forming the conductive material is further characterized as filling the hole with the conductive material.

8. The method of claim 7, wherein the step of forming the conductive material is further characterized by the conductive material comprising copper.

9. The method of claim 1, further comprising:
performing chemical mechanical polishing to form a substantially planar surface above the hole that is substantially coplanar with a top surface of a dielectric, wherein the dielectric is formed over the active circuitry.

10. The method of claim 9, further comprising:
forming an interconnect over the active circuitry having a first conductive line and a second conductive line after the step of performing chemical mechanical polishing;
forming a first via between the first conductive line and the active circuitry;
forming a second via between the second conductive line and the active circuitry;
forming a third via between the first conductive line and the conductive layer; and
forming a fourth via between the second conductive line and the conductive material.

11. The method of claim 10, wherein the step of forming the interconnect is further characterized by the first conductive line being a ground line and the second conductive line being a signal line.

12. The method of claim 10, wherein the step of forming the interconnect is further characterized by the first conductive line being a first power supply line and the second conductive line being a second power supply line.

13. The method of claim 12, wherein the step of forming the interconnect is further characterized by the first power supply line being a positive power supply line and the second power supply line being a ground line.

14. The method of claim 1, further comprising forming a dielectric layer over the active circuitry.

15. A method of forming a through-substrate via, comprising:
providing a substrate having a first major surface;
forming a hole in the substrate through the first major surface;
depositing a substantially conformal conductive layer in the hole;
depositing a substantially conformal first dielectric layer over the conductive layer;
forming a conductive material over the substantially conformal first dielectric layer;
etching a second major surface of the substrate to expose the conductive material and the substantially conformal conductive layer; and
performing chemical mechanical polishing on the first major surface to expose the conductive material and the substantially conformal conductive layer.

16. The method of claim 15, further comprising:
providing active circuitry over the first major surface;
forming an interconnect over the active circuitry having a first conductive line and a second conductive line after the step of performing chemical mechanical polishing;
forming a first via between the first conductive line and the active circuitry;
forming a second via between the second conductive line and the active circuitry;
forming a third via between the first conductive line and the substantially conformal conductive layer; and
forming a fourth via between the first conductive line and the conductive material.

17. The method of claim 15, wherein the step of forming the interconnect is further characterized by the first conductive line being a ground line and the second conductive line being a signal line.

18. The method of claim 15, wherein the step of forming the interconnect is further characterized by the first conductive line being a positive power supply line and the second conductive line being a ground line.

19. The method of claim 15, further comprising:
depositing a substantially conformal second dielectric layer prior to the step of depositing the substantially conformal conductive layer;
depositing a substantially conformal first barrier layer over the first dielectric layer; and
forming a substantially conformal second barrier layer over the second dielectric layer;
wherein the step of etching comprises grinding; and
wherein the steps of forming the first and second barrier layers are further characterized by the first and second barrier layers comprising a metal.

20. A method, comprising:
providing substrate;
forming a hole in substrate;
forming a substantially conformal first metal layer in the hole;
forming a substantially conformal dielectric layer over the substantially conformal first metal layer;
forming a seed layer over the substantially conformal dielectric layer;
forming a second metal layer by plating on the seed layer; and
removing a portion of the substrate from a major surface sufficiently to expose the substantially conformal first metal layer and the second metal layer.
